(19) United States
(12) Patent Application Publication
(10) Pub. No.: US 2018/0210304 A1
(43) Pub. Date: Jul. 26, 2018

(54) LIQUID CRYSTAL DISPLAY PANEL AND LIQUID CRYSTAL DISPLAY DEVICE

(71) Applicant: WUHAN CHINA STAR OPTOELECTRONICS TECHNOLOGY CO., LTD., Wuhan (CN)

(72) Inventor: Cong WANG, Wuhan (CN)

(73) Assignee: WUHAN CHINA STAR OPTOELECTRONICS TECHNOLOGY CO., L TD., Wuhan (CN)

(21) Appl. No.: 15/317,990

(22) PCT Filed: Jul. 12, 2016
(86) PCT No.: PCT/CN2016/089722

§ 371 Date: Dec. 12, 2016

(30) Foreign Application Priority Data
Jun. 24, 2016 (CN) 201610472786.6

(51) Int. Cl. G02F 1/1362; G09G 3/36; H01L 27/12

(52) U.S. Cl. CPC G02F 1/136286; H01L 27/124; G09G 3/3648

(57) ABSTRACT

A liquid crystal display panel is provided. The liquid crystal display panel has data lines, scan lines, and pixel units disposed between the data lines and the scan lines. The (a)^{th} type sub-pixel units of the (2n+1)^{th} column of the pixel units and the (a)^{th} type sub-pixel units of the (2n+2)^{th} column of the pixel units connect to identical data lines, respectively; and the (a)^{th} type sub-pixel units of the (2n+1)^{th} column of the pixel units and the (a)^{th} type sub-pixel units of the (2n+2)^{th} column of the pixel units connect to different scan lines, respectively.

### FIELD OF THE INVENTION

The present invention relates to a technical field of liquid crystal displays, and in particular to a liquid crystal display panel and liquid crystal display device.

### BACKGROUND OF THE INVENTION

In the prior art, adjacent sub pixels of a half source driving (HSD) pixel array share a data line, so that the number of the data lines compared with the traditional liquid crystal driving pixel array is reduced by half. Adjacent sub pixels in the same row connect to different scan lines. Two sub pixels separated by a sub pixel connect to an identical scan line. Adjacent sub pixels from top to bottom connect to different scan lines. Thus a data line is disposed between two columns of the sub pixels to increase a aperture ratio of the liquid crystal panel.

However, each data line of the existing HSD liquid crystal panel needs to provide a data signal to sub pixels at a left side and to provide a data signal to sub pixels at a right side in each frame, and the display color of the sub pixels at the left side of the data line and the right side of the data line are inconsistent. Thus some data lines need to change high potential (display color pixels) and low potential (not display color pixels) frequently when the HSD liquid crystal panel displays a solid color picture, so that the power dissipation of the driving circuit of the data line is large.

As a result, it is necessary to provide a liquid crystal display panel and a liquid crystal display device to solve the problems existing in the conventional technologies, as described above.

### SUMMARY OF THE INVENTION

An object of the present invention is to provide a liquid crystal display panel and a liquid crystal display device, which solves the technical problem of large power dissipation of the existing liquid crystal display panel and the liquid crystal display device.

To achieve the above objects, the present invention provides a liquid crystal display panel, which comprises a plurality of data lines, a plurality of scan lines, and a plurality of pixel units disposed between the data lines and the scan lines, wherein each of the pixel unit includes m type sub-pixel units, and m is a positive integer. The (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m. The (a)^{th} type sub-pixel units of the (2n+1)^{th} column of the pixel units and the (a)^{th} type sub-pixel units of the (2n+2)^{th} column of the pixel units connect to different scan lines, respectively. Different type sub-pixel units of an identical pixel unit connect to different data lines, and all types of the sub-pixel units of the identical pixel unit connect to an identical scan line. The number of the scan lines between adjacent rows of the pixel units is 1, 2 or 3.

In one embodiment of the present invention, the scan lines includes: a first scan line and a second scan line located between the (4n+1)^{th} row of the pixel units and the (4n+2)^{th} row of the pixel units; a third scan line located between the (4n+2)^{th} row of the pixel units and the (4n+3)^{th} row of the pixel units; a fourth scan line and a fifth scan line located between the (4n+3)^{th} row of the pixel units and the (4n+4)^{th} row of the pixel units; and a sixth scan line, a seventh scan line and a eighth scan line located between the (4n+4)^{th} row of the pixel units and the (4n+5)^{th} row of the pixel units.

In one embodiment of the present invention, the scan lines include: a first scan line and a second scan line located between the (4n+1)^{th} row of the pixel units and the (4n+2)^{th} row of the pixel units; a third scan line, a fourth scan line and a fifth scan line located between the (4n+2)^{th} row of the pixel units and the (4n+3)^{th} row of the pixel units; a sixth scan line and a seventh scan line located between the (4n+3)^{th} row of the pixel units and the (4n+4)^{th} row of the pixel units; and an eighth scan line located between the (4n+4)^{th} row of the pixel units and the (4n+5)^{th} row of the pixel units.

In one embodiment of the present invention, the scan lines include: a first scan line and a second scan line located between the (4n+1)^{th} row of the pixel units and the (4n+2)^{th} row of the pixel units; a third scan line, a fourth scan line and a fifth scan line located between the (4n+2)^{th} row of the pixel units and the (4n+3)^{th} row of the pixel units; a sixth scan line and a seventh scan line located between the (4n+3)^{th} row of the pixel units and the (4n+4)^{th} row of the pixel units; and an eighth scan line located between the (4n+4)^{th} row of the pixel units and the (4n+5)^{th} row of the pixel units.

In one embodiment of the present invention, the pixel units include red sub-pixel units, green sub-pixel units, and blue sub-pixel units.

In one embodiment of the present invention, the pixel units include red sub-pixel units, green sub-pixel units, blue sub-pixel units, and white sub-pixel units.

To achieve the above objects, the present invention provides a liquid crystal display panel, which comprises a plurality of data lines; a plurality of scan lines; and a plurality of pixel units disposed between the data lines and the scan lines, wherein each of the pixel units includes m type sub-pixel units, and m is a positive integer; wherein the (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m; and wherein the (a)^{th} type sub-pixel units of the (2n+1)^{th} column of the pixel units and the (a)^{th} type sub-pixel units of the (2n+2)^{th} column of the pixel units connect to different scan lines, respectively.

In one embodiment of the present invention, different type sub-pixel units of an identical pixel unit connect to different data lines.

In one embodiment of the present invention, all types of the sub-pixel units of an identical pixel unit connect to an identical scan line.

In one embodiment of the present invention, the number of the scan lines between adjacent rows of the pixel units is 1, 2, or 3.

In one embodiment of the present invention, the scan lines include: a first scan line and a second scan line located between the (4n+1)^{th} row of the pixel units and the (4n+2)^{th} row of the pixel units; a third scan line located between the (4n+2)^{th} row of the pixel units and the (4n+3)^{th} row of the pixel units; a fourth scan line and a fifth scan line located between the (4n+3)^{th} row of the pixel units and the (4n+4)^{th} row of the pixel units; and a sixth scan line, a seventh scan line and an eighth scan line located between the (4n+4)^{th} row of the pixel units and the (4n+5)^{th} row of the pixel units.

In one embodiment of the present invention, the scan lines include: a first scan line and a second scan line located between the (4n+1)^{th} row of the pixel units and the (4n+2)^{th} row of the pixel units; a third scan line, a fourth scan line, and a fifth scan line located between the (4n+2)^{th} row of the pixel units and the (4n+3)^{th} row of the pixel units; a sixth scan line and a seventh scan line located between the (4n+3)^{th} row of the pixel units and the (4n+4)^{th} row of the pixel units; and an eighth scan line located between the (4n+4)^{th} row of the pixel units and the (4n+5)^{th} row of the pixel units.

In one embodiment of the present invention, the pixel units include red sub-pixel units, green sub-pixel units, and blue sub-pixel units.

In one embodiment of the present invention, the pixel units include red sub-pixel units, green sub-pixel units, blue sub-pixel units, and white sub-pixel units.

To achieve the above objects, the present invention provides a liquid crystal display device includes a liquid crystal display panel and a backlight module, wherein the liquid crystal display panel comprises a plurality of data lines; a plurality of scan lines; and a plurality of pixel units disposed between the data lines and the scan lines, wherein each of the pixel units includes m type sub-pixel units, and m is a positive integer. The (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m. The (a)^{th} type sub-pixel units of the (2n+1)^{th} column of the pixel units and the (a)^{th} type sub-pixel units of the (2n+2)^{th} column of the pixel units connect to different scan lines, respectively.

In one embodiment of the present invention, the different type sub-pixel units of an identical pixel unit connect to different data lines.

In one embodiment of the present invention, all types of the sub-pixel units of an identical pixel unit connect to an identical scan line.

In one embodiment of the present invention, the number of the scan lines between adjacent rows of the pixel units is 1, 2, or 3.

In one embodiment of the present invention, the scan lines include: a first scan line and a second scan line located between the (4n+1)^{th} row of the pixel units and the (4n+2)^{th} row of the pixel units; a third scan line located between the (4n+2)^{th} row of the pixel units and the (4n+3)^{th} row of the pixel units; a fourth scan line and a fifth scan line located between the (4n+3)^{th} row of the pixel units and the (4n+4)^{th} row of the pixel units; and a sixth scan line, a seventh scan line and an eighth scan line located between the (4n+4)^{th} row of the pixel units and the (4n+5)^{th} row of the pixel units.

In one embodiment of the present invention, the scan lines include: a first scan line and a second scan line located between the (4n+1)^{th} row of the pixel units and the (4n+2)^{th} row of the pixel units; a third scan line, a fourth scan line, and a fifth scan line located between the (4n+2)^{th} row of the pixel units and the (4n+3)^{th} row of the pixel units; a sixth scan line and a seventh scan line located between the (4n+3)^{th} row of the pixel units and the (4n+4)^{th} row of the pixel units; and an eighth scan line located between the (4n+4)^{th} row of the pixel units and the (4n+5)^{th} row of the pixel units.

In one embodiment of the present invention, the pixel units include red sub-pixel units, green sub-pixel units, and blue sub-pixel units; or include red sub-pixel units, green sub-pixel units, blue sub-pixel units, and white sub-pixel units.

Compared with the existing liquid crystal display panel and the liquid crystal display device, the identical sub-pixel units of the (2n+1)^{th} column of the pixel units and that of the (2n+2)^{th} column of the pixel units in the liquid crystal display panel and the liquid crystal display device of the present invention connect to an identical data line, respectively. Thus the data lines cannot change to high or low potential frequently when a solid color is displayed, and the power dissipation of the liquid crystal panel can be reduced, which solves the technical problem of large power dissipation in the existing liquid crystal display panel and the liquid crystal display device.

### DESCRIPTION OF THE DRAWINGS

In order to more clearly illustrate the embodiments or the prior art technical solutions embodiment of the present invention, will implement the following figures for the cases described in the prior art or require the use of a simple introduction. Obviously, the following description of the drawings are only some of those of ordinary skill in terms of creative effort without precondition, you can also obtain other drawings based on these drawings embodiments of the present invention.

FIG. 1 is a schematic views of a first embodiment of a liquid crystal display panel.

FIG. 2 is a schematic views of a second embodiment of a liquid crystal display panel.

### DETAILED DESCRIPTION OF THE PREFERRED EMBODIMENTS

Please refer to the drawings, the components of the same sign on behalf of the same component. The following description of the embodiments with reference to the attached drawings illustrates how the present invention may be used to implement a particular embodiment.

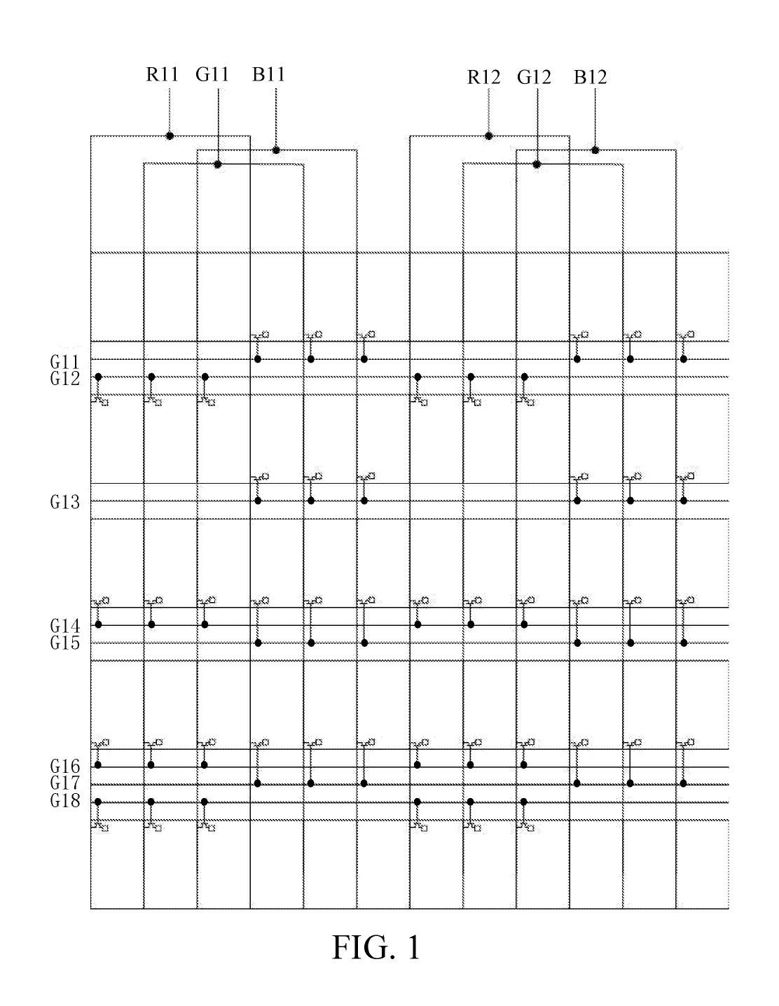

Refer to FIG. 1, which is a schematic views of a first embodiment of a liquid crystal display panel. The liquid crystal display panel of the preferred embodiment comprises a plurality of data lines, a plurality of scan lines, and a plurality of pixel units disposed between the data lines and the scan lines. In the preferred embodiment, the pixel units include red sub-pixel units, green sub-pixel units, and blue sub-pixel units.

The red sub-pixel units of the (2n+1)^{th} column of the pixel units and the red sub-pixel units of the (2n+2)^{th} column of the pixel units connect to an identical data line R11, R12 with a red signal, respectively. The green sub-pixel units of the (2n+1)^{th} column of the pixel units and the green sub-pixel units of the (2n+2)^{th} column of the pixel units connect to an identical data line G11, G12 with a green signal, respectively. The blue sub-pixel units of the (2n+1)^{th} column of the pixel units and the blue sub-pixel units of the (2n+2)^{th} column of the pixel units connect to an identical data line B11, B12 with a blue signal, respectively.

The red sub-pixel units of the (2n+1)^{th} column of the pixel units and the red sub-pixel units of the (2n+2)^{th} column of the pixel units connect to different scan lines, respectively. The green sub-pixel units of the (2n+1)^{th} column of the pixel units and the green sub-pixel units of the (2n+2)^{th} column of the pixel units connect to different scan lines, respectively. The blue sub-pixel units of the (2n+1)^{th} column of the pixel units and the blue sub-pixel units of the (2n+2)^{th} column of the pixel units connect to different scan lines, respectively.

The red sub-pixel units, green sub-pixel units and blue sub-pixel units of an identical pixel unit connect to different data lines. such as the red sub-pixel units connect to the data lines with a red signal, the green sub-pixel units connect to the data lines with a green signal, and the blue sub-pixel units connect to the data lines with a blue signal. All types of the sub-pixel units of an identical pixel unit connect to an identical scan lines.

Refer to FIG. 1, the scan lines include: a first scan line G11 and a second scan line G12 located between the (4n+1)^{th} row of the pixel units and the (4n+2)^{th} row of the pixel units; a third scan line G13 located between the (4n+2)^{th} row of the pixel units and the (4n+3)^{th} row of the pixel units; a fourth scan line G14 and a fifth scan line G15 located between the (4n+3)^{th} row of the pixel units and the (4n+4)^{th} row of the pixel units; and a sixth scan line G16, a seventh scan line G17 and a eighth scan line G18 located between the (4n+4)^{th} row of the pixel units and the (4n+5)^{th} row of the pixel units.

When the liquid crystal display panel of the preferred embodiment is used, the first scan line G11 is inputted a high level scan signal, and the (2n+2)^{th} column of the pixel units of the (4n+1)^{th} row of the pixel units is inputted a data signal from the data lines.

The first scan line G11 is inputted a low level scan signal, the second scan line G12 is inputted a high level scan signal, and the (2n+1)^{th} column of the pixel units of the (4n+2)^{th} row of the pixel units is inputted a data signal from the data lines.

The second scan line G12 is inputted a low level scan signal, the third scan line G13 is inputted a high level scan signal, and the (2n+2)^{th} column of the pixel units of the (4n+2)^{th} row of the pixel units is inputted a data signal from the data lines.

The third scan line G13 is inputted a low level scan signal, the fourth scan line G14 is inputted a high level scan signal, and the (2n+1)^{th} column of the pixel units of the (4n+3)^{th} row of the pixel units is inputted a data signal from the data lines.

The fourth scan line G14 is inputted a low level scan signal, the fifth scan line G15 is inputted a high level scan signal, and the (2n+2)^{th} column of the pixel units of the (4n+3)^{th} row of the pixel units is inputted a data signal from the data lines.

The fifth scan line G15 is inputted a low level scan signal, the sixth scan line G16 is inputted a high level scan signal, and the (2n+1)^{th} column of the pixel units of the (4n+4)^{th} row of the pixel units is inputted a data signal from the data lines.

The sixth scan line G16 is inputted a low level scan signal, the seventh scan line G17 is inputted a high level scan signal, and the (2n+2)^{th} column of the pixel units of the (4n+3)^{th} row of the pixel units is inputted a data signal from the data lines.

The seventh scan line G17 is inputted a low level scan signal, the eighth scan line G18 is inputted a high level scan signal, and the (2n+1)^{th} column of the pixel units of the (4n+5)^{th} row of the pixel units is inputted a data signal from the data lines.

An interval between the two rows of the pixel units is disposed four scan lines, twice cross scan line operations of the scan line are is operated in the interval between the two rows of the pixel units is hard. The interval between the two row of the pixel units does not gave any scan lines disposed, the utilization of the space of the interval would be reduced. Thus the aperture ratio of the liquid crystal panel would be reduced. Therefore the number of the scan lines between adjacent rows of the pixel units is preferably disposed 1, 2, or 3.

In the preferred embodiment, three scan lines are disposed between the (4n+4)^{th} row of the pixel units and the (4n+4)^{th} row of the pixel units, the scan lines are disposed together compared to only two scan lines disposed adjacent rows of the pixel units, which can increase the aperture ratio of the liquid crystal panel.

Thus the process of the display from the liquid crystal panel of the preferred embodiment can be finished.

Preferably, the pixel units of the liquid crystal panel of the preferred embodiment further include red sub-pixel units, green sub-pixel units, blue sub-pixel units, and white sub-pixel units.

In the liquid crystal panel of the preferred embodiment, the identical sub-pixel units of the (2n+1)^{th} column of the pixel units and the (2n+2)^{th} column of the pixel units connect to an identical data line, respectively. Thus the data lines cannot change to high or low potential frequently when a solid color is displayed, and the power dissipation of the liquid crystal panel can be reduced.

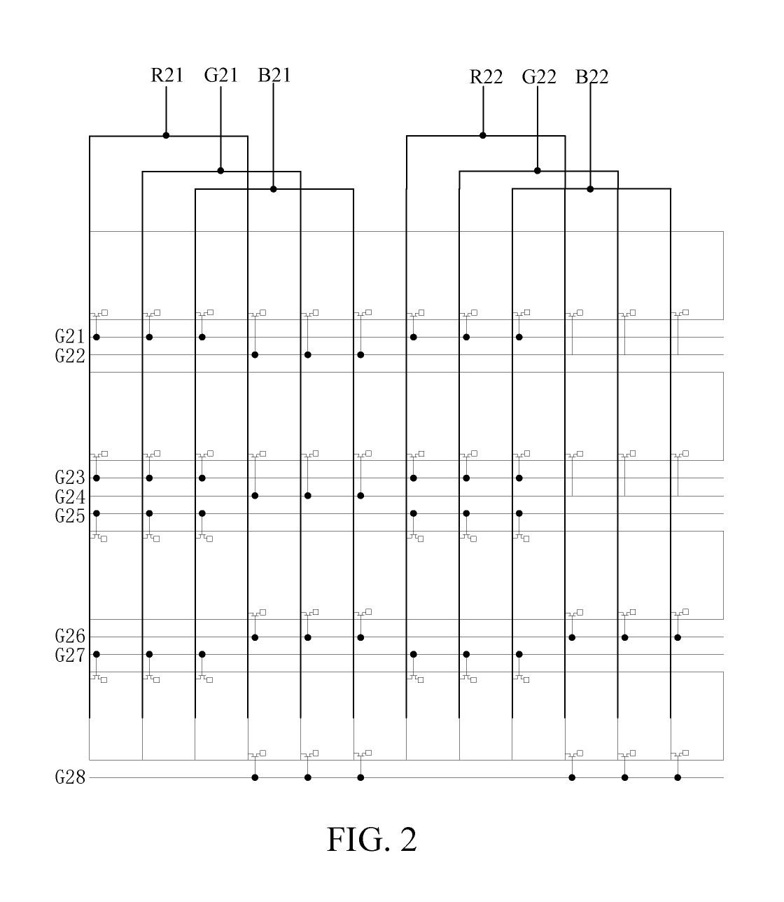

Refer to FIG. 2, which a schematic view of a second embodiment of a liquid crystal display panel. The liquid crystal display panel of the preferred embodiment comprises a plurality of data lines, a plurality of scan lines, and a plurality of pixel units disposed between the data lines and the scan lines. In the preferred embodiment, the pixel units include red sub-pixel units, green sub-pixel units, and blue sub-pixel units.

The difference of the liquid crystal panel of the preferred embodiment compared with the first embodiment is the scan lines of the preferred embodiment include: a first scan line G21 and a second scan line G22 located between the (4n+1)^{th} row of the pixel units and the (4n+2)^{th} row of the pixel units; a third scan line G23, a fourth scan line G24, and a fifth scan line G25 located between the (4n+2)^{th} row of the pixel units and the (4n+3)^{th} row of the pixel units; a sixth scan line G26 and a seventh scan line G27 located between the (4n+3)^{th} row of the pixel units and the (4n+4)^{th} row of the pixel units; and a eighth scan line G28 located between the (4n+4)^{th} row of the pixel units and the (4n+5)^{th} row of the pixel units.

The red sub-pixel units of the (2n+1)^{th} column of the pixel units and the red sub-pixel units of the (2n+2)^{th} column of the pixel units connect to an identical data line R21, R22 with a red signal, respectively. The green sub-pixel units of the (2n+1)^{th} column of the pixel units and the green sub-pixel units of the (2n+2)^{th} column of the pixel units connect to an identical data line G21, G22 with a green signal, respectively. The blue sub-pixel units of the (2n+1)^{th} column of the pixel units and the blue sub-pixel units of the (2n+2)^{th} column of the pixel units connect to an identical data line B21, B22 with a blue signal, respectively.

When the liquid crystal display panel of the preferred embodiment is used, the first scan line G21 is inputted a high level scan signal, and the (2n+1)^{th} column of the pixel units of the (4n+1)^{th} row of the pixel units is inputted a data signal from the data lines.

The first scan line G21 is inputted a low level scan signal, the second scan line G22 is inputted a high level scan signal, and the (2n+2)^{th} column of the pixel units of the (4n+1)^{th} row of the pixel units is inputted a data signal from the data lines.

The second scan line G22 is inputted a low level scan signal, the third scan line G23 is inputted a high level scan signal, and the (2n+1)^{th} column of the pixel units of the (4n+2)^{th} row of the pixel units is inputted a data signal from the data lines.

The third scan line G23 is inputted a low level scan signal, the fourth scan line G24 is inputted a high level scan signal, and the (2n+2)^{th} column of the pixel units of the (4n+2)^{th} row of the pixel units is inputted a data signal from the data lines.

The fourth scan line G24 is inputted a low level scan signal, the fifth scan line G25 is inputted a high level scan signal, and the (2n+1)^{th} column of the pixel units of the (4n+3)^{th} row of the pixel units is inputted a data signal from the data lines.

The fifth scan line G25 is inputted a low level scan signal, the sixth scan line G26 is inputted a high level scan signal, and the (2n+2)^{th} column of the pixel units of the (4n+3)^{th} row of the pixel units is inputted a data signal from the data lines.

The sixth scan line G26 is inputted a low level scan signal, the seventh scan line G27 is inputted a high level scan signal, and the (2n+1)^{th} column of the pixel units of the (4n+4)^{th} row of the pixel units is inputted a data signal from the data lines.

The seventh scan line G27 is inputted a low level scan signal, the eighth scan line G28 is inputted a high level scan signal, and the (2n+2)^{th} column of the pixel units of the (4n+4)^{th} row of the pixel units is inputted a data signal from the data lines.

An interval between the two rows of the pixel units is disposed four scan lines, twice cross line operations of the scan line are operated in the interval between the two rows of the pixel units is hard. The interval between the two row of the pixel units does not dispose any scan line, the utilization of the space of the interval would be reduced. Thus the aperture ratio of the liquid crystal panel would be reduced. Therefore the number of the scan lines disposed between adjacent rows of the pixel units is preferably 1, 2, or 3.

In the preferred embodiment, three scan lines are disposed between the (4n+4)^{th} row of the pixel units and the (4n+4)^{th} row of the pixel units, the scan lines are disposed together compared to only two scan lines disposed in adjacent rows of the pixel units, which can increase the aperture ratio of the liquid crystal panel.

Thus the process of the display from the liquid crystal panel of the preferred embodiment can be finished.

In the liquid crystal panel of the preferred embodiment, the identical sub-pixel units of the (2n+1)^{th} column of the pixel units and the (2n+2)^{th} column of the pixel units connect to an identical scan line, respectively. Thus the data lines cannot change to high or low potential frequently when a solid color is displayed, and the power dissipation of the liquid crystal panel can be reduced.

The present invention further provides a liquid crystal display device which includes a liquid crystal display panel and a backlight module, the liquid crystal display panel comprises a plurality of data lines; a plurality of scan lines; and a plurality of pixel units disposed between the data lines and the scan lines, wherein each of the pixel unit includes m type sub-pixel units, such as red sub-pixel units, green sub-pixel units, and blue sub-pixel units, or red sub-pixel units, green sub-pixel units, blue sub-pixel units, and white sub-pixel units, and m is a positive integer.

The (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m.

The (a)^{th} type sub-pixel units of the (2n+1)^{th} column of the pixel units and the (a)^{th} type sub-pixel units of the (2n+2)^{th} column of the pixel units connect to different scan lines, respectively.

Preferably, different type sub-pixel units of an identical pixel unit connect to different data lines, and all types of the sub-pixel units of an identical pixel unit connect to an identical scan line.

Preferably, the number of the scan lines between adjacent rows of the pixel units is 1, 2 or 3.

Preferably, the scan lines include: a first scan line and a second scan line located between the (4n+1)^{th} row of the pixel units and the (4n+2)^{th} row of the pixel units; a third scan line located between the (4n+2)^{th} row of the pixel units and the (4n+3)^{th} row of the pixel units; a fourth scan line and a fifth scan line located between the (4n+3)^{th} row of the pixel units and the (4n+4)^{th} row of the pixel units; and a sixth scan line, a seventh scan line and an eighth scan line located between the (4n+4)^{th} row of the pixel units and the (4n+5)^{th} row of the pixel units.

Preferably, the scan lines include: a first scan line and a second scan line located between the (4n+1)^{th} row of the pixel units and the (4n+2)^{th} row of the pixel units; a third scan line, a fourth scan line and a fifth scan line located between the (4n+2)^{th} row of the pixel units and the (4n+3)^{th} row of the pixel units; a sixth scan line and a seventh scan line located between the (4n+3)^{th} row of the pixel units and the (4n+4)^{th} row of the pixel units; and an eighth scan line located between the (4n+4)^{th} row of the pixel units and the (4n+5)^{th} row of the pixel units.

The detailed principle of the liquid crystal display device of the preferred embodiment and the said the liquid crystal display panel of the preferred embodiment are the same or similar, as you will see the related description of the liquid crystal display panel of the preferred embodiment.

The identical sub-pixel units of the (2n+1)^{th} column of the pixel units and the (2n+2)^{th} column of the pixel units in the liquid crystal display panel and the liquid crystal display device connect to an identical data line, respectively. Thus the data lines cannot change to high or low potential frequently when the solid color is displayed, and the power dissipation of the liquid crystal panel can be reduced, which solves the technical problem of large power dissipation of the existing liquid crystal display panel and the liquid crystal display device.

The present invention has been described with preferred embodiments thereof and it is understood that many changes and modifications to the described embodiments can be carried out without departing from the scope and the spirit of the invention that is intended to be limited only by the appended claims.

What is claimed is:

1. A liquid crystal display panel, comprising:
a plurality of data lines;
a plurality of scan lines; and
a plurality of pixel units disposed between the data lines and the scan lines, wherein each of the pixel unit includes m type sub-pixel units, and m is a positive integer;
wherein the (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m;
wherein the (a)^{th} type sub-pixel units of the (2n+1)^{th} column of the pixel units and the (a)^{th} type sub-pixel units of the (2n+2)^{th} column of the pixel units connect to different scan lines, respectively;
wherein different type sub-pixel units of an identical pixel unit connect to different data lines, and all types of the sub-pixel units of the identical pixel unit connect to an identical scan line; and
wherein the number of the scan lines between adjacent rows of the pixel units is 1, 2 or 3.

2. The liquid crystal display panel according to claim 1, wherein the scan lines include:
a first scan line and a second scan line located between the (4n+1)^{th} row of the pixel units and the (4n+2)^{th} row of the pixel units;
a third scan line located between the (4n+2)^{th} row of the pixel units and the (4n+3)^{th} row of the pixel units;
a fourth scan line and a fifth scan line located between the (4n+3)^{th} row of the pixel units and the (4n+4)^{th} row of the pixel units; and
a sixth scan line, a seventh scan line and a eighth scan line located between the (4n+4)^{th} row of the pixel units and the (4n+5)^{th} row of the pixel units.

3. The liquid crystal display panel according to claim 1, wherein the scan lines include:
a first scan line and a second scan line located between the (4n+1)^{th} row of the pixel units and the (4n+2)^{th} row of the pixel units;
a third scan line, a fourth scan line and a fifth scan line located between the (4n+2)^{th} row of the pixel units and the (4n+3)^{th} row of the pixel units;
a sixth scan line and a seventh scan line located between the (4n+3)^{th} row of the pixel units and the (4n+4)^{th} row of the pixel units; and
a eighth scan line located between the (4n+4)^{th} row of the pixel units and the (4n+5)^{th} row of the pixel units.

4. The liquid crystal display panel according to claim 1, wherein the pixel units include red sub-pixel units, green sub-pixel units, and blue sub-pixel units.

5. The liquid crystal display panel according to claim 1, wherein the pixel units include red sub-pixel units, green sub-pixel units, blue sub-pixel units, and white sub-pixel units.

6. A liquid crystal display panel, comprising:
a plurality of data lines;
a plurality of scan lines; and
a plurality of pixel units disposed between the data lines and the scan lines, wherein each of the pixel unit includes m type sub-pixel units, and m is a positive integer;
wherein the (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m; and
wherein the (a)^{th} type sub-pixel units of the (2n+1)^{th} column of the pixel units and the (a)^{th} type sub-pixel units of the (2n+2)^{th} column of the pixel units connect to different scan lines, respectively.

7. The liquid crystal display panel according to claim 6, wherein different type sub-pixel units of an identical pixel unit connect to different data lines.

8. The liquid crystal display panel according to claim 6, wherein all types of the sub-pixel units of an identical pixel unit connect to an identical scan line.

9. The liquid crystal display panel according to claim 6, wherein the number of the scan lines between adjacent rows of the pixel units is 1, 2 or 3.

10. The liquid crystal display panel according to claim 9, wherein the scan lines include:
a first scan line and a second scan line located between the (4n+1)^{th} row of the pixel units and the (4n+2)^{th} row of the pixel units;
a third scan line located between the (4n+2)^{th} row of the pixel units and the (4n+3)^{th} row of the pixel units;
a fourth scan line and a fifth scan line located between the (4n+3)^{th} row of the pixel units and the (4n+4)^{th} row of the pixel units; and
a sixth scan line, a seventh scan line and a eighth scan line located between the (4n+4)^{th} row of the pixel units and the (4n+5)^{th} row of the pixel units.

11. The liquid crystal display panel according to claim 9, wherein the scan lines include:
a first scan line and a second scan line located between the (4n+1)^{th} row of the pixel units and the (4n+2)^{th} row of the pixel units;
a third scan line, a fourth scan line and a fifth scan line located between the (4n+2)^{th} row of the pixel units and the (4n+3)^{th} row of the pixel units;
a sixth scan line and a seventh scan line located between the (4n+3)^{th} row of the pixel units and the (4n+4)^{th} row of the pixel units; and
a eighth scan line located between the (4n+4)^{th} row of the pixel units and the (4n+5)^{th} row of the pixel units.

12. The liquid crystal display panel according to claim 6, wherein the pixel units include red sub-pixel units, green sub-pixel units, and blue sub-pixel units.

13. The liquid crystal display panel according to claim 6, wherein the pixel units include red sub-pixel units, green sub-pixel units, blue sub-pixel units, and white sub-pixel units.

14. A liquid crystal display device including a liquid crystal display panel and a backlight module, wherein the liquid crystal display panel comprises:
a plurality of data lines;
a plurality of scan lines; and
a plurality of pixel units disposed between the data lines and the scan lines, wherein each of the pixel unit includes m type sub-pixel units, and m is a positive integer;
wherein the (a)^{th} type sub-pixel units of the (2n+1)^{th} column of the pixel units and the (a)^{th} type sub-pixel units of the (2n+2)^{th} column of the pixel units connect to an identical data line, respectively, wherein n is an integer greater than or equal to 0, and a is a positive integer less than m; and
wherein the (a)^{th} type sub-pixel units of the (2n+1)^{th} column of the pixel units and the (a)^{th} type sub-pixel units of the (2n+2)^{th} column of the pixel units connect to different scan lines, respectively.

15. The liquid crystal display device according to claim 14, wherein the different type sub-pixel units of an identical pixel unit connect to different data lines.

16. The liquid crystal display device according to claim 14, wherein all types of the sub-pixel units of an identical pixel unit connect to an identical scan line.

17. The liquid crystal display device according to claim 14, wherein the number of the scan lines between adjacent rows of the pixel units is 1, 2 or 3.

18. The liquid crystal display device according to claim 17, wherein the scan lines include:
a first scan line and a second scan line located between the (4n+1)^{th} row of the pixel units and the (4n+2)^{th} row of the pixel units;
a third scan line located between the (4n+2)^{th} row of the pixel units and the (4n+3)^{th} row of the pixel units;
a fourth scan line and a fifth scan line located between the (4n+3)^{th} row of the pixel units and the (4n+4)^{th} row of the pixel units; and
a sixth scan line, a seventh scan line and a eighth scan line located between the (4n+4)^{th} row of the pixel units and the (4n+5)^{th} row of the pixel units.

19. The liquid crystal display device according to claim 17, wherein the scan lines include:
a first scan line and a second scan line located between the (4n+1)^{th} row of the pixel units and the (4n+2)^{th} row of the pixel units;
a third scan line, a fourth scan line and a fifth scan line located between the (4n+2)^{th} row of the pixel units and the (4n+3)^{th} row of the pixel units;
a sixth scan line and a seventh scan line located between the (4n+3)^{th} row of the pixel units and the (4n+4)^{th} row of the pixel units; and
a eighth scan line located between the (4n+4)^{th} row of the pixel units and the (4n+5)^{th} row of the pixel units.

20. The liquid crystal display device according to claim 14, wherein the pixel units include red sub-pixel units, green sub-pixel units, and blue sub-pixel units; or include red sub-pixel units, green sub-pixel units, blue sub-pixel units, and white sub-pixel units.
